(19) United States
(12) Patent Application Publication
(10) Pub. No.: US 2013/0233594 A1
(43) Pub. Date: Sep. 12, 2013

(54) COMPOSITE WIRE OF SILVER-GOLD-PALLADIUM ALLOY COATED WITH METAL THIN FILM AND METHOD THEREOF

(71) Applicants: Jun-Der Lee, (US); WIRE TECHNOLOGY CO., LTD., Taichung City (TW)

(72) Inventors: Jun-Der LEE, Taichung City (TW); Hsing-Hua Tsai, Taichung City (TW); Tung-Han Chuang, Taichung City (TW)

(73) Assignees: WIRE TECHNOLOGY CO., LTD., Taichung City (TW); Jun-Der Lee, Taichung City (TW)

(21) Appl. No.: 13/774,511

(22) Filed: Feb. 22, 2013

(30) Foreign Application Priority Data
Mar. 12, 2012 (TW) 101108268

(51) Int. Cl. H01L 23/00; H01B 13/30

(52) U.S. Cl. CPC H01L 24/45; H01B 13/30
USPC 174/126.2; 427/120

(57) ABSTRACT

The invention provides a composite wire for electronic package, the composite wire including an alloy core member and a plating layer forming on a surface of the alloy core member. The alloy core member is silver-gold-palladium alloy. The plating layer is at least one layer of thin film of pure gold, pure palladium or gold-palladium alloy. The invention also provides a method for manufacturing the composite wire. The method includes steps of: (a) providing a wire rod, (b) forming a wire having a predetermined diameter from the wire rod by a plurality of processes including cold working and annealing and (c) forming a plating layer on a surface of the wire rod before step (b) or forming a plating layer on a surface of the wire after step (b) by electroplating, sputtering or vacuum evaporation.

### BACKGROUND OF THE INVENTION

1. Field of the Invention

The present invention generally relates to a composite wire and method thereof, in particular to an alloy wire for wire bonding of electronic package and method thereof.

2. Description of Related Art

Wire bonding is one of important steps of semiconductor package and light emitting diodes package. Besides providing signal and power transmission of chips and substrates, bonding wires also has a function of heat dissipation. Therefore, the bonding wires should have excellent electrical conductivity and thermal conductivity, and sufficient strength and ductility. However, the hardness of bonding wires may not too high; otherwise the chip may crack during hot pressing of wire bonding and bonding strength of bonding wires and pads may be reduced. Also, resins used in the packages generally have corrosive chloride ions and environmental moisture absorption. Accordingly, the bonding wires must have good oxidation-resistance and corrosion-resistance.

Furthermore, the heat of a first contact (ball bond) of the wire bonding may be transmitted from melting state to room temperature through the bonding wire, and thus a heat affected zone can be formed at bonding wire near the ball bond where local large grains may grow because heat may accumulate in the heat affected zone. The bonding wire may be broken from the heat affected zone with local large grains that has lower strength when performing wire pull test. Accordingly, the bonding strength may be reduced.

When the semiconductor package products and LED package products are in use, a high current density that flows through the bonding wire may cause electromigration of metallic atoms of the bonding wire. Accordingly, voids may form at one end of the bonding wire so that electrical conductivity and thermal conductivity of the bonding wire may be reduced and the bonding wire may be broken.

Currently, the bonding wires which are used in wire bonding process of the electronic industry are mainly pure gold wires and aluminum-silicon alloy wires. The aluminum-silicon alloy wire has a low strength and is easy to be corrosive so that it only can be used in electronic products which have a low requirement of reliability. The pure gold wire is a main stream in the bonding wires, but it is expensive to cause a high cost of the package product and a large number of brittle intermetallic compounds may form at the interface between pure gold wire and aluminum pad that may reduce reliability of contacts.

Copper wires were proposed to replace gold wires, for example US 2006/0186544A1 and U.S. Pat. No. 4,986,856. However, the copper is corrosive so that a surface protection is required for wire storage and transportation, and inert gas including nitrogen and hydrogen is required for wire binding. Moreover, because the material of pure copper wire is too hard, a great force may cause damage to a chip in the process of wire bonding. A pure copper wire is too hard and corrosive to apply in an advanced wire bonding technology of double ball stack. To make a compromise, wire bonding of mixing gold wire and copper wire may be used in double ball stack. However, wire bonding of mixing gold wire and copper wire causes a high material cost, poor bonding strength and high risk of galvanic corrosion at an interface between Au and Cu.

Furthermore, in order to avoid oxidation of pure copper wire, several methods were proposed, for example a copper wire plating a gold layer of U.S. Pat. No. 7,645,522B2; a copper wire plating a Pd or Pt layer of US 2003/0173659A1; and a copper wire plating an Au, Pd, Pt, Rh, Ag or nickel layer of U.S. Pat. No. 7,820,913B2. Although a pure copper wire plating a metallic layer may avoid surface oxidation and corrosion of copper wire, those plating layers of Au, Pd or Pt may be melted into copper bonding ball during formation of a ball of wire bonding so that the completed ball bond only has few element of the plating layer on its surface, and thus may be not effective to prevent package products from corrosion.

Also, even though a pure copper wire has been plated a metallic layer, the material of pure copper wire acting as core member is too hard, a great force may cause damage to a chip in the process of wire bonding. A pure copper wire covered a plating layer is too hard and corrosive to apply in an advanced wire bonding technology of double ball stack. To make a compromise, wire bonding of mixing gold wire and surface coated copper wire may be used in double ball stack. However, wire bonding of mixing gold wire and surface coated copper wire causes a high material cost, poor bonding strength and high risk of galvanic corrosion at an interface between Au and Cu.

On the other hand, when a pure copper wire plating a metallic layer was stored in room temperature for a long time, copper atoms of the core member may migrate to a surface of the plating layer to form a number of island-like Cu gathering area that may cause the oxidation and corrosion of the wire. Such atomic migration exacerbates under a high temperature. Therefore, the method for preventing the wire from oxidation and corrosion by plating a metallic layer on a surface of pure copper wire is not effective after the wire is stored for a long time.

Alternatively, one of bonding wires which is used in wire bonding is a pure silver wire. Although silver wire has excellent electrical conductivity and thermal conductivity, corrosion may be caused under a sulfur-bearing environment, and brittle intermetallic compounds such as Ag₂Al and Ag₄Al may form during pure silver wire bonding to aluminum pad.

Moreover, a pure silver wire is easy to cause ionic migration in package material which is liable to catch moisture. Specifically, a pure silver wire may produce silver ions through current reaction under an environment of moisture, and the silver ions react with oxygen to produce AgO. AgO is not stable, and may form silver atoms by deoxidization. Next, the silver atoms become silver whiskers with leaf vein toward cathode. Finally, a short of cathode and anode may happen.

Such silver ionic migration may cause semiconductor and LED package products a failure in highly accelerated stress test (HAST) with a strict condition including 148° C., 90% RH and 3.6 bias voltage. More seriously, 10² to 10³ times of difference of diffusion coefficients between silver atoms in aluminum atom matrix and aluminum atoms in silver atom matrix may cause Kirkendall voids and bonding ball failure when pure silver wire bonding to aluminum pad.

A pure silver wire plating an Au, Pd or Pt layer is disclosed in U.S. Pat. No. 6,696,756. Although a pure silver wire plating a metallic layer may avoid corrosion of silver wire and silver ionic migration, those plating layers of Au, Pd or Pt may be melted into silver free air ball during wire bonding so that the completed ball bond only has few element of the plating layer on its surface, and thus may be not effective to prevent package products from corrosion and silver ionic migration. Also, Kirkendall voids and bonding ball failure may be caused when pure silver wire bonding to aluminum pad. Such silver ionic migration may cause semiconductor and LED package products a failure in highly accelerated stress test (HAST) with a strict condition including 148° C., 90% RH and 3.6 bias voltage.

Moreover, Ag—Au—Pd alloy wire for wire bonding and method for manufacturing Ag—Au—Pd alloy wire have been disclosed in U.S. Pat. No. 8,101,123 and U.S. Pat. No. 8,101,030. Although the properties and operation of the Ag—Au—Pd alloy wires are excellent and the Ag—Au—Pd alloy wires may replace the pure gold wires in some application of products, corrosion-resistance, resistance to ionic migration, wire drawing, operation of wire bonding, bonding strength and hardness of silver alloy wires can be further improved.

### SUMMARY OF THE INVENTION

The present invention is to provide a composite wire comprising an alloy core member and a plating layer forming on a surface of the alloy core member, wherein the alloy core member may be of Ag—Au—Pd alloy and the plating layer having at least one layer of pure gold, pure palladium or Au—Pd alloy thin film. The composite wire has excellent properties of thermal conductivity, electrical conductivity, tensile strength, ductility, corrosion-resistance, ionic migration resistance, wire drawing process and bonding strength of wire bonding. The composite wire can be used in wire bonding of semi-conductors and light emitting diodes package to have free air ball formation and strength of wire pull test and ball shear test close to a pure gold wire.

In the composite wire, the weight percent of Au in the Ag—Au—Pd alloy is preferable 0.01˜30.00 wt %, the weight percent of Pd in the Ag—Au—Pd alloy is preferable 0.01˜10.00 wt % and the remainder is Ag. The plating layer has at least one layer of pure gold, pure palladium or Au—Pd alloy thin film with a thickness of 0.001˜5.0 μm. The diameter of the composite wire is preferable in range of 10˜50 μm.

The invention also provides a method for manufacturing a composite wire, comprising steps of: providing a wire rod, the wire rod is of Ag—Au—Pd alloy; forming an Ag—Au—Pd alloy core member having a predetermined diameter from the wire rod by a plurality of processes including cold working and annealing; and forming a plating layer having at least one layer of pure gold, pure palladium or Au—Pd alloy thin film on a surface of the Ag—Au—Pd alloy core member.

In the method of manufacturing the composite wire, the step of providing a wire rod preferably comprises steps of melting raw material of the wire rod to form a cast ingot by casting; and performing a cold working to the cast ingot to obtain the wire rod. In the method of manufacturing the composite wire, the step of providing a wire rod preferably comprises steps of melting raw material of the wire rod to form a wire rod by a continuous casting. In the method of manufacturing the composite wire, the cold working is wire drawing, extrusion or combination thereof.

In the method of manufacturing the composite wire, the method preferably includes a step of forming a plating layer that has at least one layer of thin film of pure gold, pure palladium or gold-palladium alloy on a surface of the wire rod by electroplating, sputtering or vacuum evaporation before the step of forming a wire having a predetermined diameter from the wire rod by a plurality of processes including cold working and annealing.

In the method of manufacturing the composite wire, the method preferably includes a step of forming a plating layer that has at least one layer of thin film of pure gold, pure palladium or gold-palladium alloy on a surface of the wire rod by electroplating, sputtering or vacuum evaporation after the step of forming a wire having a predetermined diameter from the wire rod by a plurality of processes including cold working and annealing.

In the method of manufacturing the composite wire, the weight percent of Au in the Ag—Au—Pd alloy is preferable 0.01˜30.00 wt %, the weight percent of Pd in the Ag—Au—Pd alloy is preferable 0.01˜10.00 wt % and the remainder is Ag. The plating layer has at least one layer of pure gold, pure palladium or Au—Pd alloy thin film with a thickness of 0.001˜5.0 μm. In the method of manufacturing the composite wire, the diameter of the wire rod is preferable in range of 1˜10 mm and the composite wire is preferable in range of 10˜50 μm.

### BRIEF DESCRIPTION OF DRAWING

The features of the invention believed to be novel are set forth with particularity in the appended claims. The invention itself, however, may be best understood by reference to the following detailed description of the invention, which describes an exemplary embodiment of the invention, taken in conjunction with the accompanying drawings, in which:

FIG. 1 is a cross-sectional view of a composite wire of an embodiment according to the invention;

FIG. 2 shows a flow chart of steps of manufacturing a composite wire of an embodiment according to the invention; and

FIG. 3 shows a flow chart of steps of manufacturing a composite wire of another embodiment according to the invention.

### DETAILED DESCRIPTION OF THE INVENTION

In cooperation with attached drawings, the technical contents and detailed description of the present invention are described thereinafter according to a preferable embodiment, being not used to limit its executing scope. Any equivalent variation and modification made according to appended claims is all covered by the claims claimed by the present invention.

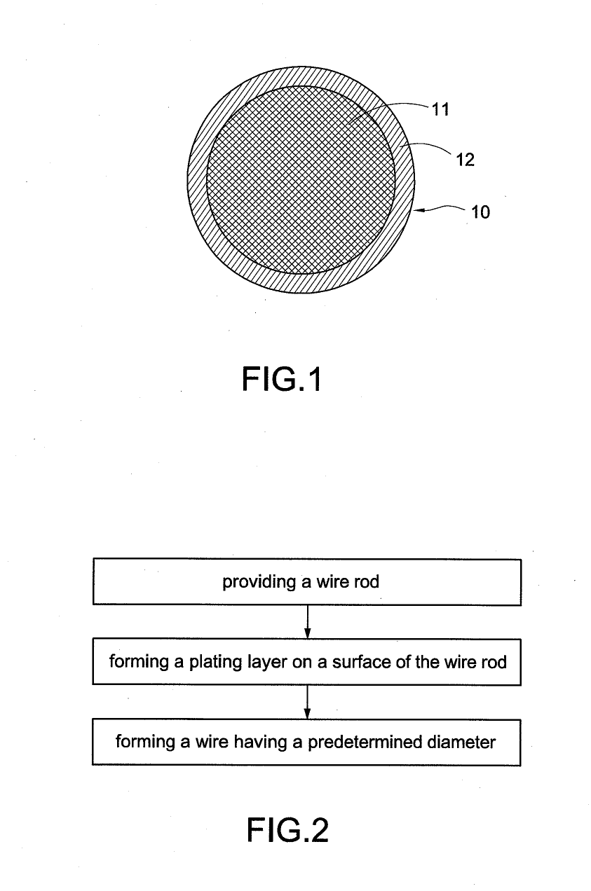

Please refer to FIG. 1. FIG. 1 shows a composite wire of an embodiment of the invention. The composite wire 10 comprises an alloy core member 11 and a plating layer 12 forming on a surface of the alloy core member 11. The alloy core member 11 is silver-gold-palladium alloy. The plating layer 12 has at least one layer of thin film of pure gold, pure palladium or gold-palladium alloy. Because the plating layer 12 is chemical inert and its surface oxides has barrier property, the core member 11 may be protected and prevent corrosion and ionic migration undermining. Also, the plating layer 12 has a function of lubrication in the formation of wire. In addition, the plating layer 12 preferably has a thickness from 0.001 μm to 5.0 μm.

The silver-palladium alloy suitably used in the present invention refers to an alloy that has a main silver component and additional components including gold and palladium, and the total content of gold and palladium is not more than the content of silver component. In addition, the present invention provides the composite wire preferably having a diameter with 10˜50 μm so as to be used for wire bonding of electronic package. The composite wire of the present invention also can be used in different technical field and usage such as audio lines, signal lines, power transmission lines, transformer lines according to the requirement of users. The diameter of composite wire can be varied according to the requirement and is not limited to the range of 10˜50 μm.

Please refer to FIG. 2. FIG. 2 is a flow chart of an embodiment of method for manufacturing composite wire of the invention. As shown in FIG. 2, the method includes a step of forming a plating layer that has at least one layer of thin film of pure gold, pure palladium or gold-palladium alloy on a surface of the wire rod by electroplating, sputtering or vacuum evaporation before the step of forming a wire having a predetermined diameter from the wire rod by a plurality of processes including cold working and annealing.

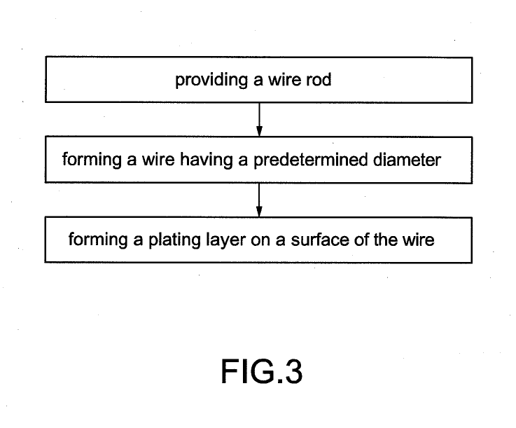

Please refer to FIG. 3. FIG. 3 is a flow chart of another embodiment of method for manufacturing composite wire of the invention. As shown in FIG. 3, the method includes a step of forming a plating layer that has at least one layer of thin film of pure gold, pure palladium or gold-palladium alloy on a surface of the wire rod by electroplating, sputtering or vacuum evaporation after the step of forming a wire having a predetermined diameter from the wire rod by a plurality of processes including cold working and annealing.

(Improvement in Effectiveness)

The invention provides a composite wire 10 comprising an alloy core member 11 and a plating layer 12 forming on a surface of the alloy core member 11. The alloy core member 11 is silver-gold-palladium alloy. The plating layer 12 has at least one layer of thin film of pure gold, pure palladium or gold-palladium alloy.

The addition of palladium to the alloy core member 11 with silver as the main component can prevent Kirkendall voids and electrolytic ionic migration while wire bonding with aluminum pad. The improvement in effectiveness may result from extremely low diffusion rate of the palladium atom. The extremely low diffusion rate of the palladium atom also can significantly inhibit the growth of intermetallic compounds (IMC) such as Ag₂Al and Ag₄Al. Further, the palladium atom can first form palladium oxides under an environment of moisture to inhibit the dissociation of silver and reduce the speed of ionic migration of silver. Therefore, the invention provides the Ag—Au—Pd alloy core member 11 that has advantageous properties of silver including low electrical resistance, high thermal conductivity and excellent ductility without drawbacks such as corrosion of product that uses pure silver wire or pure silver wire covered its surface with a plating layer of Au, Pd or Pt bonding with aluminum pad, growth of IMC, Kirkendall voids and electrolytic ionic migration.

The invention provides the plating layer 12 of pure gold, pure palladium or Au—Pd alloy thin film forming on a surface of the Ag—Au—Pd alloy core member 11. The plating layer 12 can enhance corrosion-resistance and ionic migration undermining, and provide lubrication to wire and drawing die. Also, the plating layer 12 can modify micro defects which exist on the surface of wire to avoid the growth of crack that comes from local stress concentrating to those micro defects. Therefore, the invention has an advantage that wire is not easy to break during the wire drawing process because a metallic thin film forms on a surface of the wire rod.

The invention provides the composite wire having better strength, ductility, oxidation-resistance and corrosion-resistance than a traditional aluminum silicon wire. In addition, compared to the traditional wire bonding using a gold wire, the composite wire of the invention can significantly reduce the growth of IMC on an interface between bonding ball and aluminum pad. The package industrials have been annoyed with the problems that IMC of the gold wire caused the cracks of wire bonding interface and the failure of products. The growth speed of IMC of composite wire of the invention bonding to aluminum pad may be reduced to about 60% than pure gold wire bonding to aluminum pad thereof, reduced to about 20% than pure silver wire bonding to aluminum pad thereof.

Also, compared to the traditional wire bonding using a copper wire, the composite wire of the invention can completely avoid oxidation and corrosion of pure copper without inert gas during the process of wire bonding, and significantly enhance the reliability of products. Because there has no protective inert gas, for example 99.99% nitrogen; 95% nitrogen and 5% hydrogen, been required in the method of the invention, the cost of production can be reduced. Even though the copper is covered with a plating layer of Au, Pd or Pt, the copper atoms of core member may migrate to a surface of the plating layer, and cause oxidation and corrosion. However, the composite wire 10 comprising Ag—Au—Pd alloy core member 11 and a plating layer 12 having at least one layer of pure gold, pure palladium or Au—Pd alloy thin film forming on a surface of the Ag—Au—Pd alloy core member 11 of the invention can prevent metallic atom of alloy core member 11 migrating to a surface of the plating layer 12.

Moreover, because the material of pure copper wire and pure copper wire covered a plating layer of Au, Pd or Pt is too hard, a great force may cause damage to a chip in the process of wire bonding. The material of pure copper wire and pure copper wire covered a plating layer is too hard and corrosive to apply in an advanced wire bonding technology of double ball stack. To make a compromise, wire bonding of mixing gold wire and copper wire may be used in double ball stack. However, wire bonding of mixing gold wire and copper wire causes a high material cost, poor bonding strength and high risk of galvanic corrosion at an interface between Au and Cu. The composite wire 10 comprising Ag—Au—Pd alloy core member 11 and a plating layer 12 having at least one layer of pure gold, pure palladium or Au—Pd alloy thin film forming on a surface of the Ag—Au—Pd alloy core member 11 of the invention can prevent the above drawbacks, and has a high reliability far more than the material of pure copper wire and pure copper wire covered a plating layer of Au, Pd or Pt.

In addition, the operative parameter of wire bonding of the composite wire of the invention is the same to the traditional pure gold wire thereof. The operative parameter may be used directly, and not required to be tuned in, and thus save time, avoid operative faults and increase yield. Because there has no protective inert gas been required in the method of the invention, the cost of protective inert gas and its supplying equipment can be saved.

Next, compared to a traditional Ag—Au—Pd alloy wire, because the composite wire 10 of the invention has a plating layer 12 of pure gold, pure palladium or Au—Pd alloy thin film forming on a surface of the Ag—Au—Pd alloy core member 11, the composite wire 10 has a better resistance to corrosion and ionic migration undermining. The electrical resistance of an Ag—Au—Pd alloy wire without a plating layer of pure gold, pure palladium or Au—Pd alloy thin film is slightly higher than a pure gold wire thereof due to alloying elements. The electrical resistance of the composite wire of the invention is close to a pure gold wire thereof, because the composite wire 10 of the invention has a plating layer 12 of metallic thin film forming on a surface of the Ag—Au—Pd alloy core member 11 to provide a better transmitting path for electrons.

As to hardness, the composite wire 10 of the invention that has a plating layer 12 of metallic thin film forming on a surface of the Ag—Au—Pd alloy core member 11 has a slight lower hardness than a traditional Ag—Au—Pd alloy wire, and slight higher than pure gold wire. Accordingly, a bonding power and a bonding force of the composite wire 10 of the invention having a plating layer 12 of metallic thin film required when wire bonding are lower than an Ag—Au—Pd alloy wire without a plating layer of metallic thin film thereof, and close to a pure gold wire thereof. The high bonding power and bonding force may increase a risk that the chip is punched through and cracks.

On the other hand, except aluminum silicon wire uses ultrasonic bonding without heating chip and substrate, the other wires use thermal compressive bonding which has to heat chip and substrate. A heating temperature about 100° C. is required for bonding a pure gold wire, but the heating temperature about 150° C. is required for bonding a Ag—Au—Pd alloy wire to gain a preferable bonding effect. The composite wire of the invention has a high concentration of Au and Pd gathering on a surface of fused alloy ball during free air balls forming so that wetness and bonding strength of fused Ag—Au—Pd alloy ball with the surface of aluminum pad can increase. Accordingly, a heating temperature required for bonding the composite wire 10 of the invention having a plating layer 12 of pure gold, pure palladium or Au—Pd alloy thin film forming on a surface of the Ag—Au—Pd alloy core member 11 is about 100° C. that is the same to the pure gold wire.

As to the yield of bonding wires, the plating layer 12 formed on a surface of Ag—Au—Pd alloy core member 11 of the invention can provide lubrication to the composite wire 10 and drawing die during the process of wire drawing. Also, the plating layer 12 can modify micro defects which exist on the surface of wire to avoid the growth of crack that comes from local stress concentrating to those micro defects. Therefore, the invention has an advantage that wire is not easy to break during the wire drawing process because a metallic thin film forms on a surface of the wire rod.

### EXAMPLES

An Ag-8.5 wt % Au-3.5 wt % Pd alloy wire with a diameter of 20 μm is used as alloy core member 11 of the invention. The test results of properties of an Ag-8.5 wt % Au-3.5 wt % Pd alloy wire with a plating layer of pure gold thin film, an Ag-8.5 wt % Au-3.5 wt % Pd alloy wire with a plating layer of pure palladium thin film and an Ag-8.5 wt % Au-3.5 wt % Pd alloy wire with a plating layer of Au—Pd alloy thin film compared to the Ag-8.5 wt % Au-3.5 wt % Pd alloy wire without a plating layer are shown in table 1. Also, the results of reliability test of the Ag-8.5 wt % Au-3.5 wt % Pd alloy wire with a plating layer of pure gold thin film, the Ag-8.5 wt % Au-3.5 wt % Pd alloy wire with a plating layer of pure palladium thin film and the Ag-8.5 wt % Au-3.5 wt % Pd alloy wire with a plating layer of Au—Pd alloy thin film are shown in table 2.

TABLE 1
Test results of properties of composite wires plating
with a metallic thin film compared to an Ag-8.5 wt %
Au-3.5 wt % Pd alloy wire without a plating layer

| | Composite wires | | |
|---|---|---|---|
| | | | Au—Pd alloy |
| Properties | Au thin film | Pd thin film | thin film |
| Formation of | Higher | Higher | Higher |
| wire drawing | | | |
| Electric | Lower | Higher | Slightly lower |
| resistance coefficient | | | |
| Hardness | Lower | Higher | Slightly lower |
| Wire bonding | Higher | Higher | Higher |
| operation | | | |
| Oxidation-resistance | Higher | Higher | Higher |
| Corrosion-resistance | Higher | Higher | Higher |
| Bring down | No change | Higher | Slightly higher |
| electromigration | | | |
| Bring down | No change | Higher | Slightly higher |
| silver ionic migration | | | |
| Protective inert | Not required | Not required | Not required |
| gas for wire bonding | | | |
| operation | | | |
| EFO power of | Lower | Slightly lower | Slightly lower |
| wire bonding | | | |
| Bonding force of | Lower | Slightly lower | Slightly lower |
| bonding wire | | | |
| Bonding strength | Higher | Higher | Higher |
| of bonding wire | | | |
| Efficiency of | Higher | Higher | Higher |
| wire bonding | | | |
| Yield of bonding | Higher | Higher | Higher |
| wire | | | |

TABLE 2
Reliability test results of composite
wires plating with a metallic thin film

| | Composite wires | | |
|---|---|---|---|
| | | | Au—Pd alloy |
| Reliability test | Au thin film | Pd thin film | thin film |
| 1. 168 hrs | Pass | Pass | Pass |
| Precondition Test | | | |
| 2. PCT 96 hrs | Pass | Pass | Pass |
| (Pressure Cooker Test) | | | |
| 3. Temperature | Pass | Pass | Pass |
| Cycling Test (TCT1000 | | | |
| cycles) | | | |
| 4. Temperature & | Pass | Pass | Pass |
| Humidity Test (THT1000 | | | |
| hrs) | | | |
| 5. High | Pass | Pass | Pass |
| Temperature Storage | | | |
| Test(HTST 1000 hrs) | | | |
| 6. Low | Pass | Pass | Pass |
| Temperature Storage Test | | | |
| (LTST 1000 hrs) | | | |

While the invention is described in by way of examples and in terms of preferred embodiments, it is to be understood that the invention is not limited thereto. On the contrary, the aim is to cover all modifications, alternatives and equivalents falling within the spirit and scope of the invention as defined by the appended claims.

What is claimed is:

1. A composite wire, comprising an alloy core member and a plating layer forming on a surface of the alloy core member, wherein the alloy core member is of Ag—Au—Pd alloy.

2. The composite wire according to claim 1, wherein the weight percent of Au in the Ag—Au—Pd alloy is 0.01˜30.00 wt %, the weight percent of Pd in the Ag—Au—Pd alloy is 0.01˜10.00 wt % and the remainder is Ag.

3. The composite wire according to claim 1, wherein the plating layer has at least one layer of pure gold, pure palladium or Au—Pd alloy thin film.

4. The composite wire according to claim 1, wherein the thickness of the plating layer is 0.001˜5.0 μm.

5. The composite wire according to claim 1, wherein the diameter of the composite wire is in range of 10˜50 μm.

6. A method for manufacturing a composite wire, comprising steps of
providing a wire rod, the wire rod is of Ag—Au—Pd alloy;
forming an Ag—Au—Pd alloy core member having a predetermined diameter from the wire rod by a plurality of processes including cold working and annealing; and
forming a plating layer having at least one layer of pure gold, pure palladium or Au—Pd alloy thin film on a surface of the Ag—Au—Pd alloy core member.

7. The method for manufacturing a composite wire according to claim 6, wherein the cold working is wire drawing, extrusion or combination thereof.

8. The method for manufacturing a composite wire according to claim 6, wherein the step of forming a plating layer is performed before or after the step of forming an Ag—Au—Pd alloy core member.

9. The method for manufacturing a composite wire according to claim 6, wherein the weight percent of Au in the Ag—Au—Pd alloy is 0.01˜30.00 wt %, the weight percent of Pd in the Ag—Au—Pd alloy is 0.01˜10.00 wt % and the remainder is Ag.

10. The method for manufacturing a composite wire according to claim 6, wherein the thickness of the plating layer is 0.001˜5.0 μm.
